(19) United States
(12) Patent Application Publication
(10) Pub. No.: US 2016/0021757 A1
(43) Pub. Date: Jan. 21, 2016

(54) METHOD AND DEVICE FOR FABRICATING MULTI-PIECE SUBSTRATE

(71) Applicant: MICRO CRAFT K.K., Okayama-shi, Okayama (JP)

(72) Inventor: Yorio HIDEHIRA, Okayama-shi (JP)

(73) Assignee: Micro Craft K.K.

(21) Appl. No.: 14/775,655

(22) PCT Filed: Mar. 13, 2014
(86) PCT No.: PCT/JP2014/056730

§ 371 Date: Sep. 11, 2015

(30) Foreign Application Priority Data
Mar. 13, 2013 (JP) 2013-050679

(51) Int. Cl. H05K 3/00

(52) U.S. Cl. CPC H05K 3/0097

(57) ABSTRACT

Provided are a multi-piece board fabrication method and apparatus which are capable of efficiently bonding a frame and a non-defective board piece together, thereby efficiently fabricating a multi-piece board comprising a plurality of non-defective board pieces. The method and apparatus are configured to cause a board piece conveyance mechanism to extract and hold a board piece stored in a board piece stacker and couple the board piece with a frame placed on a retaining table located in a first working area, and, after moving the retaining table from the first working area to a second working area, apply an adhesive to a coupled region between the board piece and the frame by using a dispenser to thereby fix a positional relationship therebetween.

### TECHNICAL FIELD

The present invention relates to a multi-piece substrate or board which is a single board incorporating therein a plurality of board pieces, and more specifically to a fabrication method and apparatus for a multi-piece board which is a single board incorporating therein a plurality of non-defective board pieces by means of engagement and bonding.

### BACKGROUND ART

Among circuit boards, there is a multi-piece board which is a single board incorporating therein a plurality of board pieces. As regards the multi-piece board, it is necessary for each of the plurality of board pieces to be composed of a non-defective board piece capable of satisfying predetermined given performance. In reality, however, it is difficult to fully eliminate a multi-piece board including a defective board piece which does not have the given performance. On the other hand, an approach to, just because one of a plurality of board pieces comprised in a multi-piece board is a defective, discarding the entire multi-piece board together with the remaining one or more non-defective board pieces, has problems in view of not only manufacturing cost but also efficient use of resources.

For this reason, when forming a multi-piece board, there has been employed a technique of attaching a plurality of board pieces to a frame. This makes it possible to discard a defective board piece and attach only a non-defective board piece to a frame to thereby provide a multi-piece board whose board pieces are fully composed of non-defectives, while achieving efficient use of resources.

However, in conventional techniques, steps of: attaching and setting a non-defective board piece to a frame on a board retaining jig; fastening the frame and the non-defective board piece together by a tape and further bonding them together by an adhesive to thereby prepare a multi-piece board assembly; then, after subjecting the adhesive to curing, removing the tape used for fastening the frame and the non-defective board piece together have been manually performed. This causes a problem of deterioration in operation efficiency and difficulty in enhancing productivity. (See the following Patent Document 1).

Meanwhile, a jig for retaining a board (board retaining jig) needs to be prepared for each type of board, because a size, shape, hole position, etc., of a board generally varies depending on a type of board.

However, there is a problem that considerable cost is required to fabricate a board retaining jig. Moreover, there exists a situation where it is not easy to fabricate a board retaining jig conforming to a required accuracy. It is also necessary to ensure a storage space for such board retaining jigs, i.e., indirect cost is required therefor.

The following Patent Document 6 presents an invention designed to fabricate a multi-piece board while automatically correcting a positional relationship between a frame and a non-defective board piece. However, fastening between the frame and the non-defective board piece is manually performed using a tape. This process seems inefficient. Moreover, the frame and the non-defective board piece are partially fastened by a tape. Thus, there is a problem that, even after completion of a positional adjustment between the frame and the non-defective board piece, a relative position between the frame and the non-defective board piece is likely to change during or after the taping.

### CITATION LIST

### Patent Document

Patent Document 1: JP 2000-252605A

Patent Document 2: JP 2002-43702A

Patent Document 3: JP 2002-289985A

Patent Document 4: JP 2003-69190A

Patent Document 5: JP 2011-23657A

Patent Document 6: JP 2005-537684A

### SUMMARY OF INVENTION

### Technical Problem to be Solved

Therefore, the present invention is intended to solve the above problems, and an object thereof is to provide a multi-piece board fabrication method and apparatus which are capable of automatically engaging a non-defective board piece with a frame and then efficiently bonding the frame and the non-defective board piece together, thereby efficiently fabricating a multi-piece board comprising a plurality of non-defective board pieces.

### Means for Solving the Technical Problem

According to a first aspect of the present invention, there is provided a multi-piece board fabrication apparatus for fabricating a multi-piece board in which a plurality of board pieces are attached to a frame. The apparatus comprises: a working table having a horizontally spreading working area; a linear guide extending in a first direction in such a manner as to divide the area of the working table into a first working area and a second working area; a board piece stacker disposed within the first working area and configured to releasably store a stack of non-detective board pieces; a board piece conveyance mechanism attached to the linear guide at a position on the side of the first working area and configured to sequentially extract each of the board pieces stored in the board piece stacker and convey the extracted board piece to a given position along the first direction; a retaining table disposed on the working table in such a manner as to be movable between the first and second working areas to allow positioning and fixing operations between the frame and each of the plurality of board pieces to be performed; a retaining table conveyance mechanism supporting the retaining table and configured to move the retaining table over a range from the first working area to the second working area along a second direction perpendicular to the first direction; and a dispenser installed to the linear guide at a position on the side of the second working area in such a manner as to be movable along the first direction and configured to supply an adhesive for bonding together the frame and each of the board pieces located on the retaining table, wherein the apparatus are operable to cause the board piece conveyance mechanism to sequentially extract and hold each of the board pieces stored in the board piece stacker and couple the board piece with the frame placed on the retaining table located in the first working area, and, after moving the retaining table from the first working area to the second working area, apply the adhesive to a coupled region between the board piece and the frame by using the dispenser to thereby fix a positional relationship therebetween.

In a preferred embodiment, the apparatus comprises: a first retaining table and a first retaining table conveyance mechanism configured to move the first retaining table over the range from the first working area to the second working area along the second direction; and a second retaining table disposed adjacent to the first retaining table, and a second retaining table conveyance mechanism configured to move the second retaining table over the range from the first working area to the second working area along the second direction, wherein the apparatus is operable, when positioning and coupling operations between the frame and each of the board pieces are being performed on the first retaining table located in the first working area, to concurrently perform application of the adhesive to the coupled region between the frame and the board piece, on the second retaining table located in the second working area, and, when the positioning and coupling operations between the frame and each of the board pieces are being performed on the second retaining table located in the first working area, to concurrently perform the application of the adhesive to the coupled region between the first frame and the board piece in the second working area. According to this feature, it becomes possible to more efficiently fabricate the multi-piece boards.

According to a second aspect of the present invention, there is provided a method of fabricating a multi-piece board in which a plurality of board pieces are attached to a frame, using the above apparatus. The method comprises the steps of: causing the board piece conveyance mechanism to sequentially extract and hold each of the board pieces stored in the board piece stacker; moving the board piece conveyance mechanism in the first direction to the given position along the linear guide and then performing positioning and coupling between the board piece and the frame placed on the retaining table located in the first working area; moving the retaining table from the first working area to the second working area; and applying the adhesive to a coupled region between the board piece and the frame by using the dispenser to thereby fix a positional relationship therebetween.

In a preferred embodiment, when the apparatus further comprises: a first retaining table and a first retaining table conveyance mechanism configured to move the first retaining table over the range from the first working area to the second working area along the second direction; and a second retaining table disposed adjacent to the first retaining table, and a second retaining table conveyance mechanism configured to move the second retaining table over the range from the first working area to the second working area along the second direction, the method comprises the steps of: when positioning and coupling operations between the frame and each of the board pieces are being performed on the first retaining table located in the first working area, to concurrently perform application of the adhesive to the coupled region between the frame and the board piece, on the second retaining table located in the second working area; and when the positioning and coupling operations between the frame and each of the board pieces are being performed on the second retaining table located in the first working area, to concurrently perform the application of the adhesive to the coupled region between the first frame and the board piece in the second working area.

According to a third aspect of the present invention, there is provided a method of fabricating a multi-piece board in which a plurality of board pieces are attached to a frame. The method comprises the steps of: forming a plurality of board pieces constituting a single board for mounting a given electronic component; separating the formed board pieces into a group of non-defective board pieces having good quality satisfying a given criterion and a group of defective board pieces unsatisfying the given criterion, and selecting only the non-defective board pieces; providing a single-piece frame for supporting a plurality of board pieces, and engaging a plurality of the non-defective board pieces each having a bridge provided on a side edge thereof to protrude outwardly from the side edge, with recesses of the frame for receiving therein respective ones of the bridges of the non-defective board pieces, via the bridges; adhering the frame and the non-defective board pieces engaged with the frame onto a pressure-sensitive adhesive sheet; and bonding together corresponding ones of the bridges of the non-defective board pieces and the recesses of the frame by an adhesive.

In the third aspect of the present invention, it becomes possible to bond and fix the frame and the non-defective board pieces together easily, accurately and efficiently.

In a preferred embodiment, the pressure-sensitive adhesive sheet is supported by a metal plate.

In another preferred embodiment, the pressure-sensitive adhesive sheet has a property that high adhesion is exhibited at a relatively low temperature, and the adhesion deteriorates at a relatively high temperature. In this case, a multi-piece board having the non-defective board pieces integrated with the frame may be adhered onto the pressure-sensitive adhesive sheet at the relatively low temperature, and the multi-piece board may be separated from the pressure-sensitive adhesive sheet at the relatively high temperature.

In this preferred embodiment, the relatively low temperature may be set to 10 to 30° C., and the relatively high temperature may be set to about 60° C.

Thus, the method according to the third aspect of the present invention makes it possible to facilitate extraction of a non-defective multi-piece board by means of heating and cooling.

In still another preferred embodiment, the step of providing includes acquiring respective positional information of the frame and each of the non-defective board pieces, and establishing engagement therebetween while controlling positions thereof based on the position information.

Thus, it becomes possible to acquire respective positional information of the frame and each of the non-defective board pieces and fit each of the non-defective board pieces into an appropriate position of the frame with a high degree of accuracy.

In yet still another preferred embodiment, the method further comprises a step of acquiring positional information of a given location of the frame and the non-defective board pieces adhered onto the pressure-sensitive adhesive sheet, by using an imaging camera, and storing the acquired positional information. This makes it possible to, during an operation of assembling a given electronic component to a multi-piece board in a subsequent step, enhance accuracy in controllability of the assembling while making the assembling more efficient.

According to a fourth aspect of the present invention, there is provided an apparatus for fabricating a multi-piece board, wherein the multi-piece board comprises: a non-defective board piece having good quality satisfying given criteria, selected from among a plurality of board pieces constituting a single board for mounting a given electronic component; and a frame for supporting a plurality of the non-defective board piece, and wherein each of the non-defective board pieces has a bridge provided on a side edge thereof and formed to protrude outwardly from the side edge, and the frame is provided with recesses engageable with the respective bridges of the non-defective board pieces during engagement between the frame and the non-defective board pieces. The apparatus comprises: a pressure-sensitive adhesive sheet for allowing an integral structure of the frame and the plurality of non-defective board pieces engaged with each other to be adhered thereonto; and a dispenser operable, after the integral structure of the frame and the plurality of non-defective board pieces is adhered onto the pressure-sensitive adhesive sheet and positioned, to supply an adhesive for bonding together corresponding ones of the recesses of the frame and the bridges of the non-defective board pieces.

In a preferred embodiment, the apparatus further comprises a positional information acquisition element configured to acquire positional information of a given point of the frame and positional information of a given location of each of the non-defective board pieces supported by the frame.

In this preferred embodiment, the positional information acquisition element is configured to acquire the positional information by analyzing images which are taken from the frame and the non-defective board pieces supported by the frame, by using an imaging camera.

In another preferred embodiment, the apparatus further comprises: a retaining table retaining the metal plate which supports the multi-piece board adhered onto the pressure-sensitive adhesive sheet; and a position control mechanism configured to control a position of the retaining table.

In yet another preferred embodiment, the apparatus further comprises: an arm configured to conveyably hold the non-defective board piece; and an arm movement mechanism configured to move the arm and control a position of the arm. More preferably, in this case, the position control mechanism comprises a mechanism configured to control a rotational position of the retaining table.

In another further preferred embodiment, the apparatus is configured to control respective positions of the arm and the retaining table to thereby establish engagement between each of the non-defective board pieces and the frame.

In still a further preferred embodiment, the apparatus further comprises a control mechanism configured to control a position of the dispenser, wherein the control mechanism is operable, after completion of the engagement between the frame and the non-defective board pieces, to positionally control the dispenser to supply the adhesive to a bonding region between corresponding ones of the bridges of the non-defective board pieces and the recesses of the frame.

Thus, in the apparatus according to the fourth aspect of the present invention, it is possible to move the non-defective board piece and the frame relatively with respect to each other in a plane (in an X-Y plane) and freely position them to thereby provide good operation efficiency.

Further, in a preferred embodiment, the apparatus is characterized in that the retaining table is provided with a rotation mechanism.

Thus, in the apparatus according to the fourth aspect of the present invention, even in a situation where angular positions of the non-defective board piece and the frame are relatively mismatched with each other, the retaining table can be rotated to allow the angular positions of the non-defective board piece and the frame to become relatively matched with each other, so that it becomes possible to fit the non-defective board piece into the frame with a high degree of accuracy.

Further, in the apparatus according to the fourth aspect of the present invention, the integral structure of the frame and the non-defective board pieces is adhered onto the pressure-sensitive adhesive sheet whose adhesion property varies according to temperature.

Thus, the apparatus according to the fourth aspect of the present invention makes it possible to facilitate extraction of a non-defective multi-piece board by heating and cooling the pressure-sensitive adhesive sheet. Further, the pressure-sensitive adhesive sheet may be supported by a meal plate. In this case, it becomes possible to enhance accuracy and efficiency in the temperature control.

In an additional preferred embodiment, positional information of the frame is acquired from thereabove by a first imaging camera, and positional information of each of the non-defective board pieces is acquired from therebelow by a second imaging camera. In this way, positioning between the frame and each of the non-defective board pieces can be performed.

Thus, in the additional preferred embodiment, it becomes possible to acquire respective positional information of the frame and each of the non-defective board pieces and fit each of the non-defective board pieces into an appropriate position of the frame with a high degree of accuracy.

The apparatus according to the fourth aspect of the present invention is configured to automatically apply the adhesive to the coupled region between each of the non-defective board pieces and the frame.

Further, in the apparatus according to the fourth aspect of the present invention, the dispenser and the retaining table can be moved relatively with respect to each other in a plane (in an X-Y plane), so that it becomes possible to apply the adhesive to a desired position with a high degree of accuracy.

### Effect of Invention

As above, the multi-piece board fabrication method and apparatus of the present invention can efficiently fabricate a non-defective multi-piece board.

### BRIEF DESCRIPTION OF DRAWINGS

FIG. 1 is a perspective view illustrating a part of a multi-piece board fabrication apparatus according to a first embodiment of the present invention.

FIG. 2 is a perspective view illustrating a part of the multi-piece board fabrication apparatus according to the first embodiment, when viewed from an angle different from that in FIG. 1.

FIG. 3 is a partially enlarged view of the multi-piece board fabrication apparatus in FIG. 1.

FIG. 4 is a partially enlarged view of the multi-piece board fabrication apparatus in FIG. 2.

FIG. 5 is a partially enlarged view illustrating retaining tables and the surroundings of the multi-piece board fabrication apparatus in FIG. 1, when viewed from the same angle as that in FIG. 3.

FIG. 6 is a top plan view of a non-defective board piece.

FIG. 7 is a top plan view of a frame.

FIG. 8 is a top plan view illustrating a state after two non-defective board pieces are fitted into the frame.

FIG. 9 is a flowchart of a process of fabricating the multi-piece board according to the first embodiment of the present invention.

FIG. 10 is a perspective view schematically illustrating a state during an operation of adhering the frame to a metal plate.

FIG. 11 is a perspective view illustrating a state in which the metal plate having the frame adhered thereonto is set on a retaining table.

FIG. 12 is a perspective view schematically illustrating a state in which an image of a board piece being suction-held is taken by an imaging camera to thereby acquire positional information of the board piece.

FIG. 13 is an explanatory diagram illustrating a state of position control for board pieces.

FIG. 14 is an explanatory diagram illustrating a state during an operation of coupling board pieces with the frame by a board piece conveyance mechanism.

FIG. 15 is an explanatory diagram illustrating a state during a preparatory operation for applying an adhesive by a dispenser.

FIG. 16 is a partially enlarged view illustrating a state during an operation of applying an adhesive to a bonding region between a bridge of a non-defective board piece and a recess of the frame engaged with the bridge.

FIG. 17 is a schematic diagram illustrating operation states of two shuttles.

FIG. 18 is a top plan view illustrating a semifinished multi-piece board in which a non-defective board piece is fixed to one of two engagement spaces of a frame, and the other engagement space is in a vacant state.

FIG. 19 is a top plan view of a non-defective board piece to be assembled into the vacant engagement space of the semifinished multi-piece board.

FIG. 20 is a top plan view illustrating a state after a non-defective board piece is assembled into the vacant engagement space of the semifinished multi-piece board in FIG. 18.

FIG. 21 is a top plan view illustrating a state after a non-defective board piece assembled into the engagement space of the semifinished multi-piece board in FIG. 18 is fixed.

### DESCRIPTION OF EMBODIMENTS

With reference to the drawings, the present invention will now be described based on embodiments thereof. As a general rule, throughout all of the figures illustrating the embodiments, the same element or component is assigned with the same reference sign, and its duplicated description will be omitted.

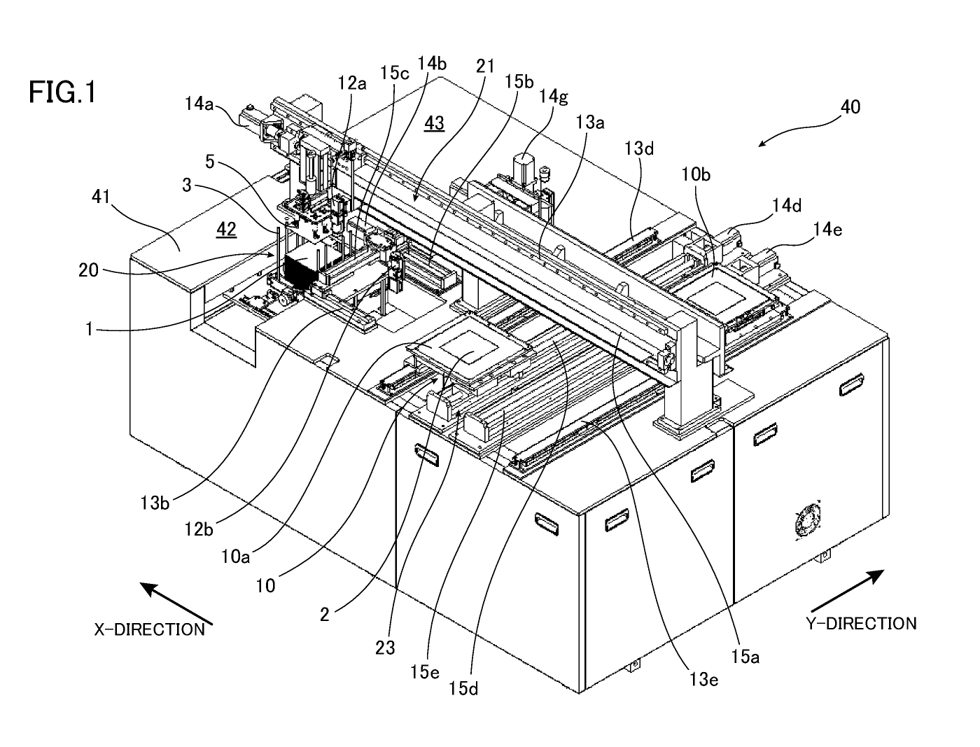

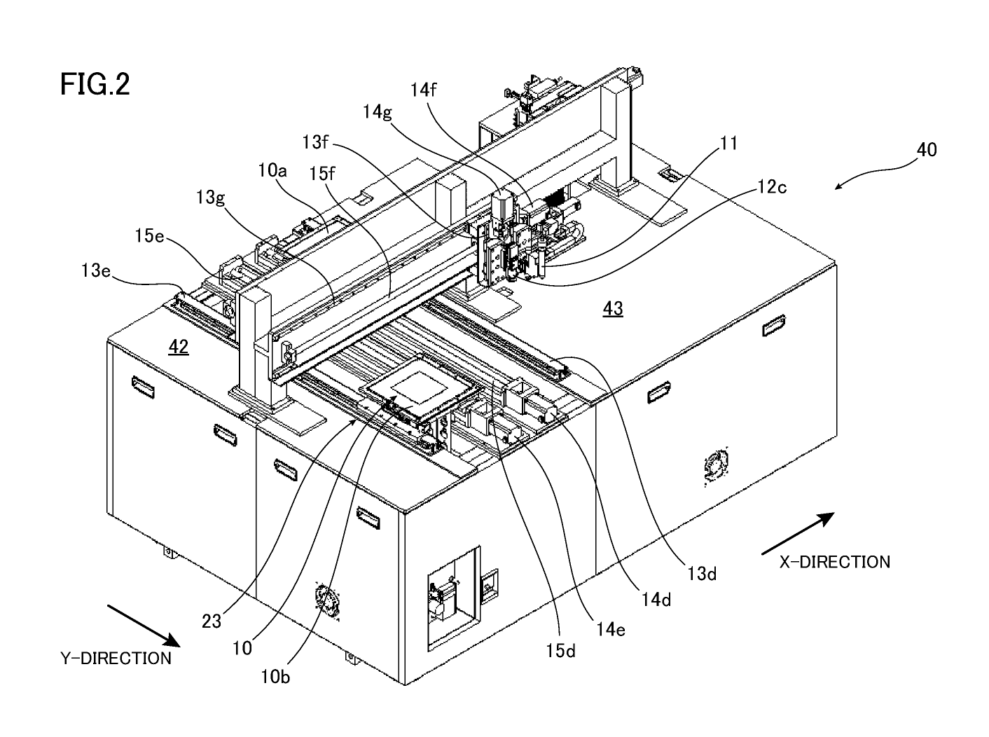

The present invention will be described based on a representative embodiment thereof. FIGS. 1 and 2 are overall perspective views illustrating a multi-piece board fabrication apparatus according to a first embodiment of the present invention, which is designed to fabricate a multi-piece board 6 in which a plurality of board pieces are attached to a frame. The multi-piece board fabrication apparatus 40 for fabricating the multi-piece board 6 comprises a working table 41 having a working area spreading horizontally, i.e., in an X-direction and a Y-direction.

The multi-piece board fabrication apparatus 40 also comprises a linear guide 13a extending in a first direction, i.e., the X-direction, in such a manner as to divide the working area of the working table into two areas: a first working area 42 and a second working area 43.

Within the first working area 42, a board piece stacker 20 configured to releasably store a stack of board pieces 1 is disposed.

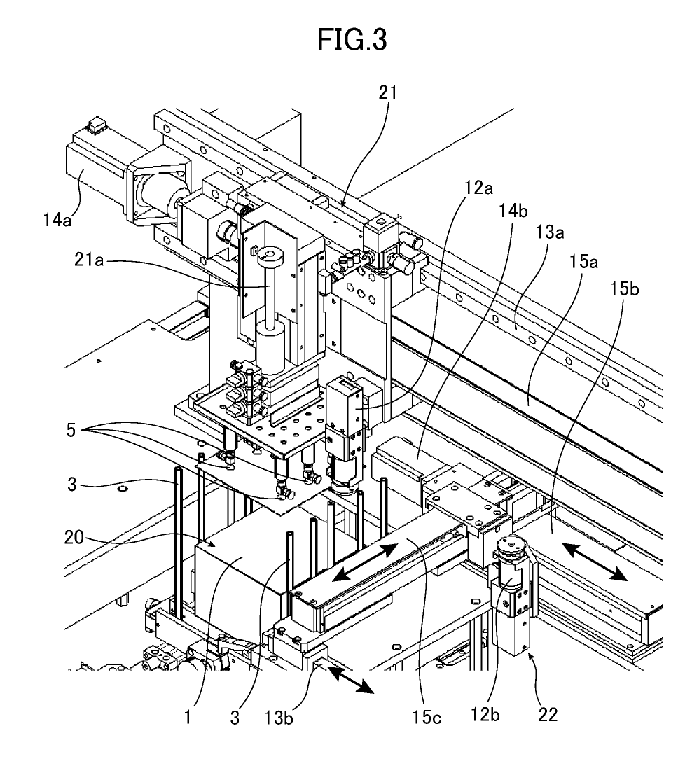

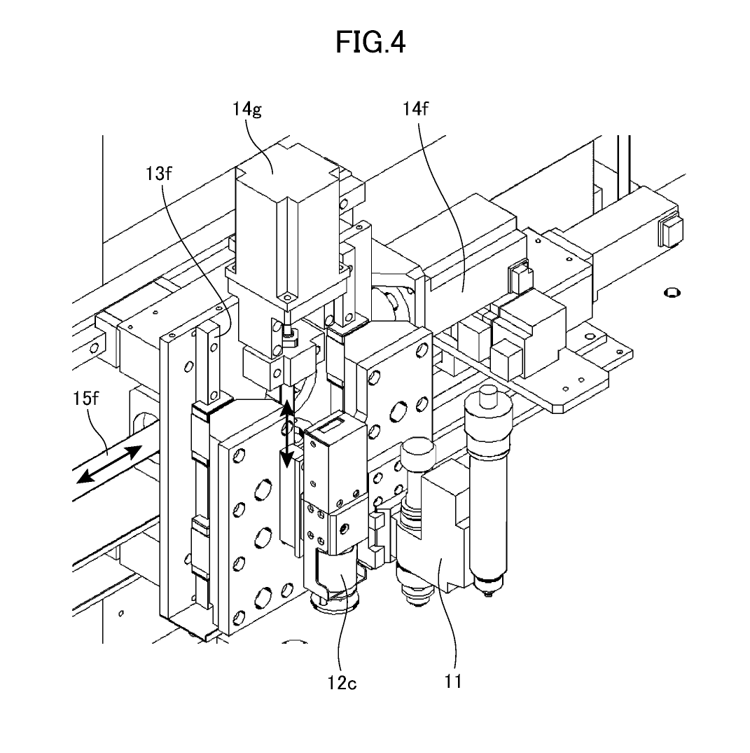

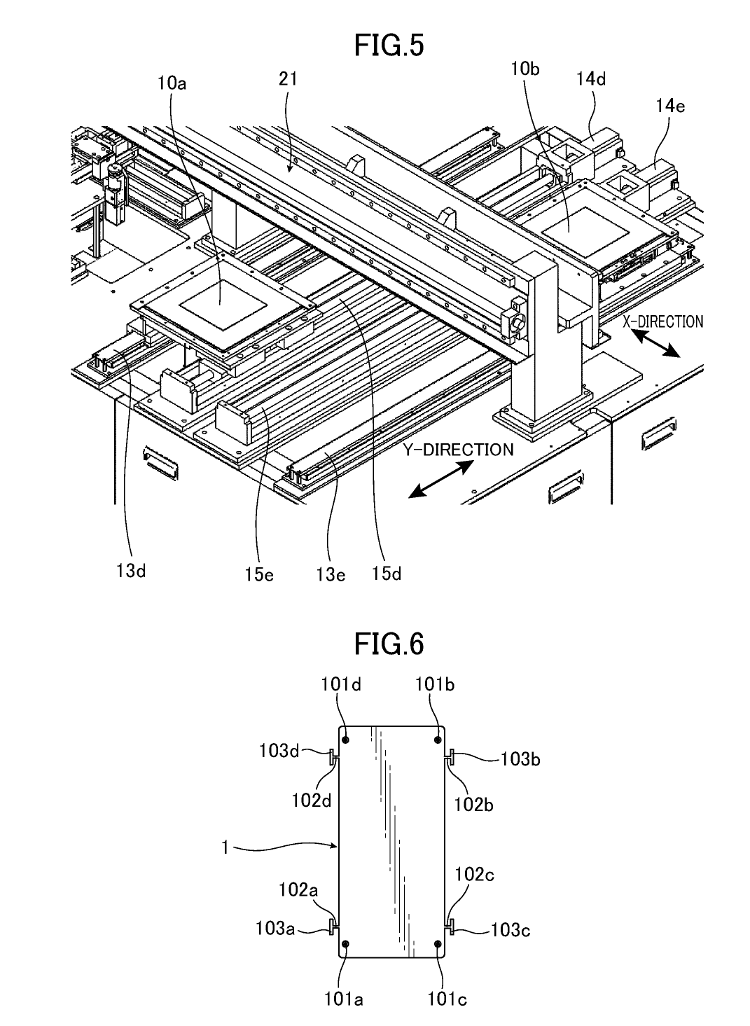

Referring to FIGS. 3 to 5, partially enlarged views of the multi-piece board fabrication apparatus 40 are illustrated.

FIG. 6 is a top plan view illustrating a board piece 1 in this embodiment. The board piece 1 means a component composed of a board which is provided with a given wiring and into which a given electronic component is to be subsequently assembled. In this embodiment, regarding a plurality of board pieces 1 comprised in the multi-piece board 6, positional information thereof must be accurately figured out to adequately perform a subsequent electronic component assembling operation. As used in this embodiment, the term “board piece” means a so-called non-defective board piece capable of satisfying performance criteria as a given finished product. The board piece 1 in this embodiment is formed in a rectangular shape, and four corners of the board piece 1 are marked, respectively, with four reference marks 101a, 101b, 101c and 101d at predetermined positions. The reference marks are used to acquire positional information of the board piece 1 to accurately perform position control for the board piece 1. The board piece 1 also has four bridges 102a, 102b, 102c, 102d, where each of them are provided to protrude outwardly from a peripheral side edge thereof in such a manner as to be engageable with respective recesses of an aftermentioned frame 2. Each of the bridges is formed in a structure having an enlarged distal end (103a, 103b, 103c, 103d).

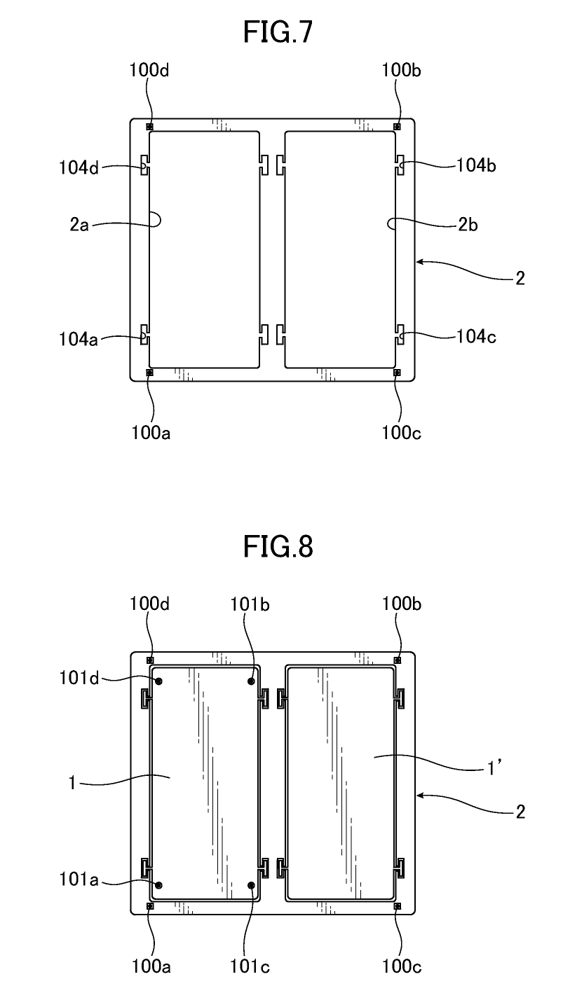

FIG. 7 is a top plan view illustrating a top plan view of a frame 2 in this embodiment. The multi-piece board 6 in this embodiment comprises a plurality of board pieces each of which is provided with a given wiring and into which a given electronic component such as a circuit component is to be assembled in a subsequent step. The frame 2 is a component constituting the multi-piece board 6 and having a function of positioning and fixing the plurality of board pieces on the multi-piece board 6. The frame 2 illustrated in FIG. 7 has a two spaces 2a, 2b for allowing the two board pieces 1 illustrated in FIG. 6 to be assembled thereinto, respectively.

The frame 2 in this embodiment has four corners marked, respectively, with four predetermined reference marks 100a, 100b, 100c, 100d. The frame 2 also has four recesses 104a, 104b, 104c, 104d provided in an inner side edge defining each of the two spaces 2a, 2b, at respective positions corresponding to the four bridges of the board piece 1. In an engagement or coupling operation with the board piece 1, each of the four bridges 102a, 102b, 102c, 102d is engaged with a corresponding one of the recesses 104a, 104b, 104c, 104d to establish the coupling. The reference marks 100a, 100b, 100c, 100d of the frame 2 are used to acquire positional information of the frame 2 to accurately perform position control for the frame 2. They are also used for position control during the operation of engaging or coupling the board pieces 1 with the frame 2 to prepare a multi-piece board 6 (an unfinished multi-piece board at this stage).

In the form of a top plan view, FIG. 8 illustrates one example of the multi-piece board 6 prepared by fitting two board pieces 1, respectively, into the two spaces 2a, 2b, and engaging the four bridges 102a, 102b, 102c, 102d of each of the board pieces 1 with corresponding ones of the recesses 104a, 104b, 104c, 104d of the frame 2 to couple the board pieces 1 with the frame 2.

The board piece stacker 20 of the multi-piece board fabrication apparatus 40 for fabricating the multi-piece board 6 is equipped with a plurality of guide shafts 3. A preparatory operation for fabrication of the multi-piece board 6 is performed by setting a plurality of board pieces 1 at a given stacked position by means of contact between the board pieces 1 and the guide shafts 3. Thus, the multi-piece board fabrication apparatus 40 according to this embodiment is capable of disposing a plurality of board pieces 1 approximately at a fixed position and releasably set the board pieces 1 for fabrication of the multi-piece board 6.

Further, the multi-piece board fabrication apparatus 40 comprises a board piece conveyance mechanism 21 attached to the linear guide 13a at a position on the side of the first working area 42 and configured to sequentially extract each of the board pieces 1 stored in the board piece stacker 20 in a stacked manner and convey the extracted board piece 1 to a given position along the first direction (X-direction). The board piece conveyance mechanism 21 comprises the linear guide 13a, a drive motor 14a, and a ball screw 15a.

The piece conveyance mechanism 21 is configured to suction-hold the board piece 1 from the board piece stacker 20 by means of negative pressure to thereby extract the board piece 1 from the board piece stacker 20, and convey the suction-held board piece 1 toward a retaining table 10 (10a, 10b).

The retaining table 10 (10a, 10b) in this embodiment is located on a side opposite to the board piece stacker 20 with respect to an X-directional center of the working area of the working table 41, and has a planar surface for performing an operation of coupling a plurality of the board pieces 1 with the frame 2 based on given positional information to fabricate the multi-piece board 6.

The board piece conveyance mechanism 21 is comprised of the linear guide 13a, the drive motor 14a and the ball screw 15a, and configured to move linearly reciprocatingly in the X-direction between the board piece stacker 20 and the retaining table 10 (10a, 10b) along the linear guide 13a. In order to sequentially lift up and extract each of a stack of board pieces 1 from the board piece stacker 20, the board piece conveyance mechanism 21 also comprises a movement mechanism movable in a stacker direction along which a plurality of board pieces 1 are stacked (in an up-down direction, i.e., a Z-direction), and a mechanism for holding each of the board pieces 1. The board piece conveyance mechanism 21 is configured to suction-hold the board piece 1 by means of negative pressure and then convey the suction-held board piece 1. Although a vacuum-suction system is employed as the holding mechanism in this embodiment, the holding mechanism is not limited to the vacuum-suction system.

In this embodiment, the board piece conveyance mechanism 21 is provided with a board piece imaging unit 22 comprising an imaging camera 12b for taking an image of a board piece 1 being conveyed so as to read positional information of the board piece 1.

Specifically, the imaging camera 12b is mounted to the board piece imaging unit 22 to take an image of an extracted board piece 1 to acquire positional information of the board piece 1, wherein the imaging camera 12b is disposed to take an image of the board piece 1 from therebelow. The board piece imaging unit 22 is configured to be movable in the X-direction and Y-direction in such a manner as to conform to an intended imaging region on an as-needed basis. Specifically, the imaging camera 12b can be freely moved within a range of movement in two mutually orthogonal directions, according to a movement mechanism comprised of two sets of a linear guide 13b (for movement in the X-direction), a drive motor 14b (for movement in the X-direction) and ball screws 15b (for movement in the X-direction), 15c (for movement in the Y-direction) (two sets of a linear guide 13b and a drive motor 14b (for movements in the X-direction and Y-direction), and two ball screws 15b (for movement in the X-direction), 15c (for movement in the Y-direction).

In this embodiment, an imaging camera 12a is further mounted to the board piece conveyance mechanism 21 to take an image of the frame 2, and configured to be movable together with the board piece conveyance mechanism 21, and disposed to take an image of the board pieces 1 and the frame 2 located on the retaining table 10 (10a, 10b) from thereabove so as to accurate acquire positional information thereof.

A large number of holes (not illustrated) are formed in the retaining table 10 (10a, 10b), and a vacuum pump (not illustrated) can be coupled to the retaining table 10 (10a, 10b) so as to suction-hold a metal plate 4 on an upper surface of the retaining table. The retaining table 10 (10a, 10b) is provided with a rotation mechanism. Thus, in a situation where angular positions of a board piece 1 and the frame 2 are relatively mismatched with each other, the retaining table 10 can be rotated by a given angle to thereby correct the mismatching between the angular positions of the board piece 1 and the frame 2.

A retaining table conveyance mechanism 23 (23a, 23b) is comprised of a linear guide (13d, 13e), a drive motor (14d, 14e) and a ball screw (15d, 15e), and configured to be movable linearly reciprocatingly between a board piece setting position and an adhesive application position. The retaining table conveyance mechanism 23 is configured to satisfy a positional relationship that a movement direction thereof is perpendicular to a movement direction of the board piece conveyance mechanism 21.

The multi-piece board fabrication apparatus 40 further comprises a dispenser 11 installed to the linear guide 13a of the board piece conveyance mechanism 21 at a position on the side of the second working area in such a manner as to be movable along the first direction (X-direction) and configured to supply an adhesive 44 between the frame 2 and each of the board pieces 1 to bond them together.

The dispenser 11 is disposed above the retaining table 10 (10a, 10b) and configured to apply the adhesive 44 to a coupled region between the frame 2 and each of the board pieces 1 in such a manner as to fix a positional relationship therebetween.

An adhesive application unit comprises the dispenser 11 for supplying the adhesive 44, a linear guide 13f, a drive motor 14g, and a boll screw (not illustrated), whereby the dispenser 11 is movable in the up-down direction. Further, the adhesive application unit comprises a support mechanism for the dispenser 11, and an imaging camera 12c mounted to the support mechanism to take an image of the board pieces 1 and the frame 2 from thereabove so as to acquire positional information thereof. Further, according to another movement mechanism comprised of a linear guide 13g, a drive motor 14f and a ball screw 15f, the dispenser 11 can be moved in a direction perpendicular to the movement direction of the retaining table conveyance mechanism 23.

The retaining table 10 of the multi-piece board fabrication apparatus 40 is composed of a pair of retaining tables 10a, 10b each disposed on the working table 41 in such a manner as to be movable between the first and second working areas 42, 43 to allow positioning and fixing operations between the frame 2 and each of the plurality of board pieces 1 to be performed. Further, the retaining table conveyance mechanism 23 comprises a pair of retaining table conveyance mechanisms 23a, 23b each supporting a corresponding one of the retaining tables 10a, 10b and configured to move the corresponding one of the retaining tables 10a, 10b over the range from the first working area 42 to the second working area 43 along a second direction, i.e., the Y-direction, perpendicular to the first direction. The retaining table conveyance mechanism 23a comprises the linear guide 13d, the drive motor 14d and the ball screw 15d, and the retaining table conveyance mechanism 23b comprises the linear guide 13e, the drive motor 14e and the ball screw 15e. A set of the retaining table 10a and the retaining table conveyance mechanism 23a and a set of the retaining table 10b and the retaining table conveyance mechanism 23b are arranged side-by-side, and the retaining table conveyance mechanisms 23a, 23b are arranged to extend parallel to each other in such a manner as to move corresponding ones of the retaining tables 10a, 10b in the second direction (Y-direction). In this embodiment, the set of the retaining table 10a and the retaining table conveyance mechanism 23a will hereinafter be referred to as “first shuttle”, and the set of the retaining table 10b and the retaining table conveyance mechanism 23b will hereinafter be referred to as “second shuttle”. In this embodiment, respective operations to be performed in the first shuttle and the second shuttle are approximately the same in terms of content, but different from each other in terms of execution timing. Specifically, the first and second shuttles are configured to perform a certain operation alternately.

As above, in the multi-piece board fabrication apparatus 40, a plurality of board pieces 1 each capable of satisfying given performance criteria are stored in the board piece stacker 20 in a stacked manner.

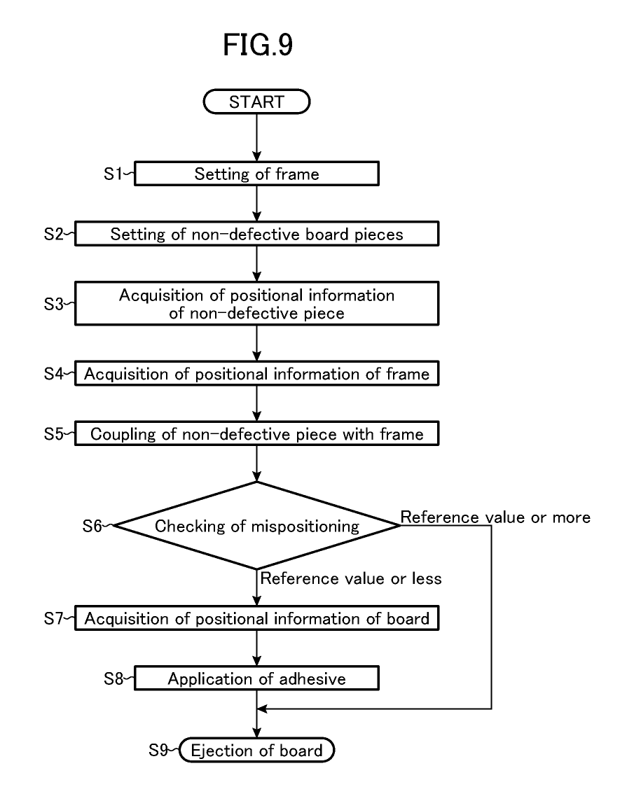

Next, with reference to the flowchart in FIG. 9, an operation of the apparatus according to this embodiment will be described.

In advance of fabrication of the multi-piece board 6 in this embodiment, a plurality of metal plates 4 each having a pressure-sensitive adhesive sheet 30 preliminarily adhered thereon are prepared. This process needs to be completed before activating the multi-piece board fabrication apparatus 40.

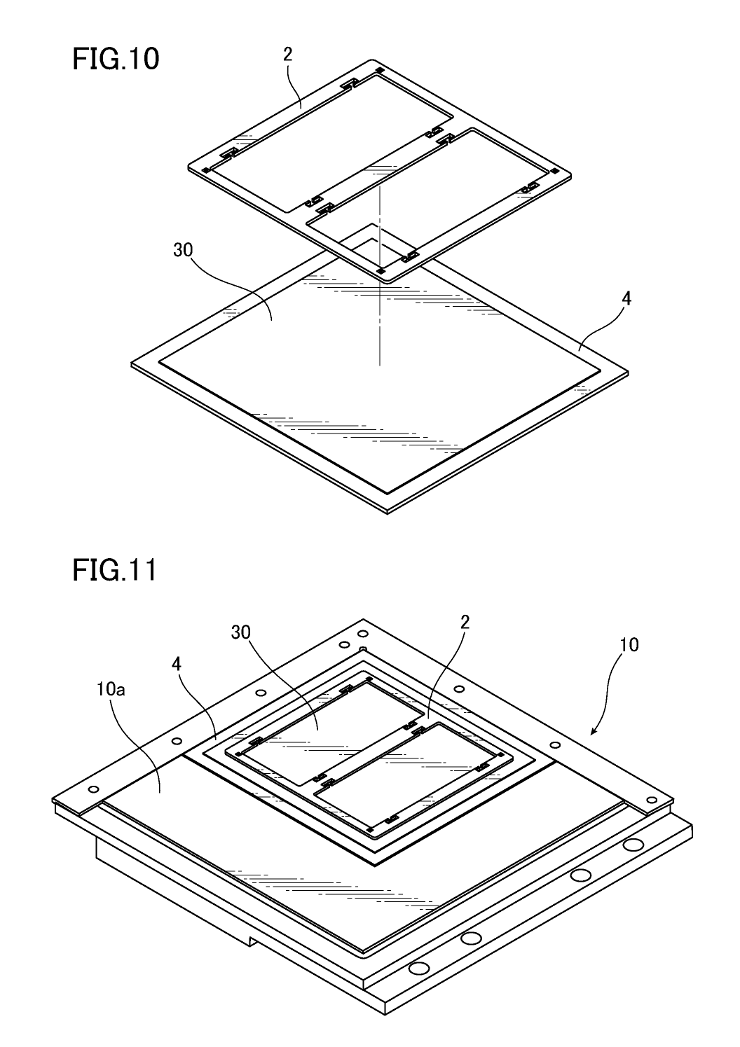

First of all, the metal plate 4 having the pressure-sensitive adhesive sheet 30 preliminarily adhered thereon is provided, and the frame 2 is adhered onto the pressure-sensitive adhesive sheet 30, as illustrated in FIG. 10. This process is manually performed.

Then, as illustrated in FIG. 11, the metal plate 4 with the frame 2 adhered thereon is set on the retaining table 10. (S1). With a view to allowing the imaging camera 12a to read a position of the frame 2 efficiently and accurately in a subsequent step, it is desirable that the frame 2 is always disposed on the metal plate 10 in the same positional relationship. After setting on the retaining table 10 the metal plate 4 having the pressure-sensitive adhesive sheet 30 on which the frame 2 is adhered, the vacuum pump coupled to the retaining table 10 is activated to apply a negative pressure to a back surface of the pressure-sensitive adhesive sheet 30 via the holes of the retaining table 10 to thereby suction-hold the metal plate 4 with respect to the retaining table 10.

In this embodiment, the pressure-sensitive adhesive sheet 30 has thermosensitivity capable of repeating an adhesive state and a non-adhesive state according changes in temperature. As used in this specification, the term “thermosensitivity” of a pressure-sensitive adhesive sheet means a property that high adhesion is exhibited at a relatively low temperature, and the adhesion deteriorates at a relatively high temperature. As the thermosensitive pressure-sensitive adhesive sheet 30, it is possible to use, for example, Intelimer tape produced by NITTA Corporation. A temperature at which the frame is adhered onto the pressure-sensitive adhesive sheet 30 is generally room temperature, preferably 10 to 30° C. The use of the thermosensitive pressure-sensitive adhesive sheet 30 makes it possible to easily peel a finished multi-piece board 6 from the pressure-sensitive adhesive sheet 30 in a relatively high temperature state just after completion of curing of the applied adhesive 44. In case of the Intelimer tape produced by NITTA Corporation, an adhesion rate decreases by 90% or more, at a temperature of 60° C. or more.

Then, a stack of board pieces 1 each capable of satisfying a given product criterion, selected among a large number of board pieces 1, are set in the board piece stacker 20. (S2).

Then, the board piece conveyance mechanism 21 is moved toward the board piece stacker 20. Then, a suction arm for applying a vacuum-suction force from the board piece conveyance mechanism 21 to a surface of a top one of the stack of board pieces 1 is moved downwardly, and operable, when the top board piece 1 is detected, to suction-hold the detected board piece 1 from thereabove by using a suction pad 5 attached to a distal end thereof and extract the suction-held board piece 1 from the board piece stacker 20. More specifically, after suction-holding the board piece 1, the board piece conveyance mechanism 21 is moved upwardly to a position where the suction-held board piece 1 is subjected to image processing.

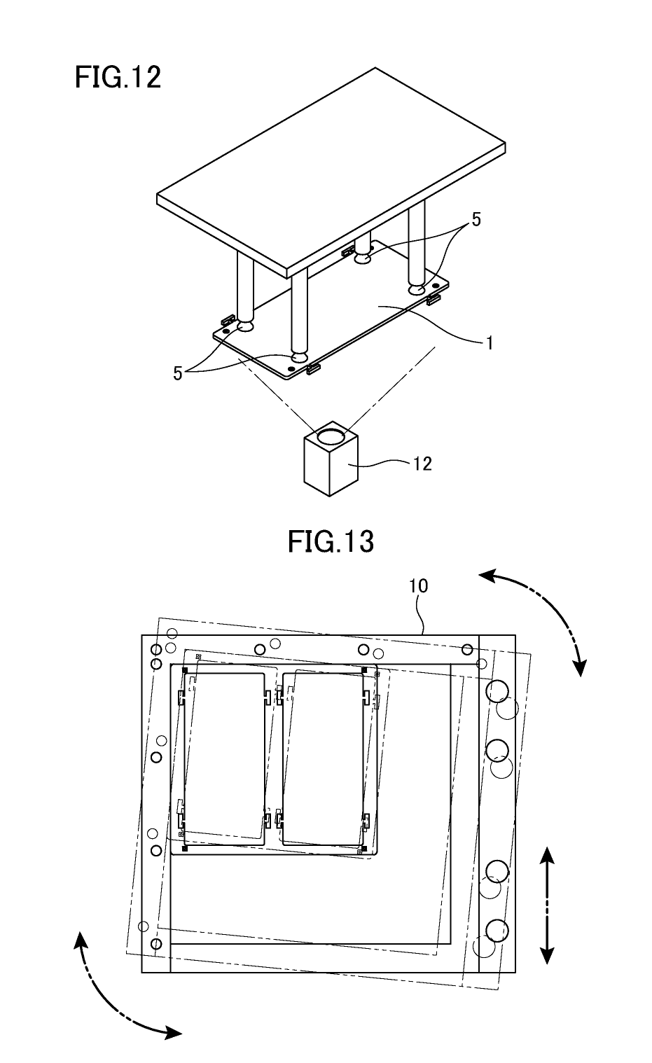

Then, at a given position between the board piece stacker 20 and the retaining table 10 along the X-direction, positional information of the suction-held board piece 1 is collected through image processing. (S3). In this process, as illustrated in FIG. 12, an image of the preliminarily-marked reference marks 101a, 101b, 101c and 101d of the board piece 1 being suction-held by the board piece conveyance mechanism 21 is taken from therebelow by the imaging camera 12b. Respective center positions of the reference marks 101a, 101b, 101c and 101d are stored in a control unit (not illustrated). Further, respective X- and Y-coordinates of the center positions of the reference marks 10 (101a to 101d) are compared with reach other to calculate a position and a rotational angle (angular position) of the suction-held board piece 1, and the calculation result is also stored in the control unit.

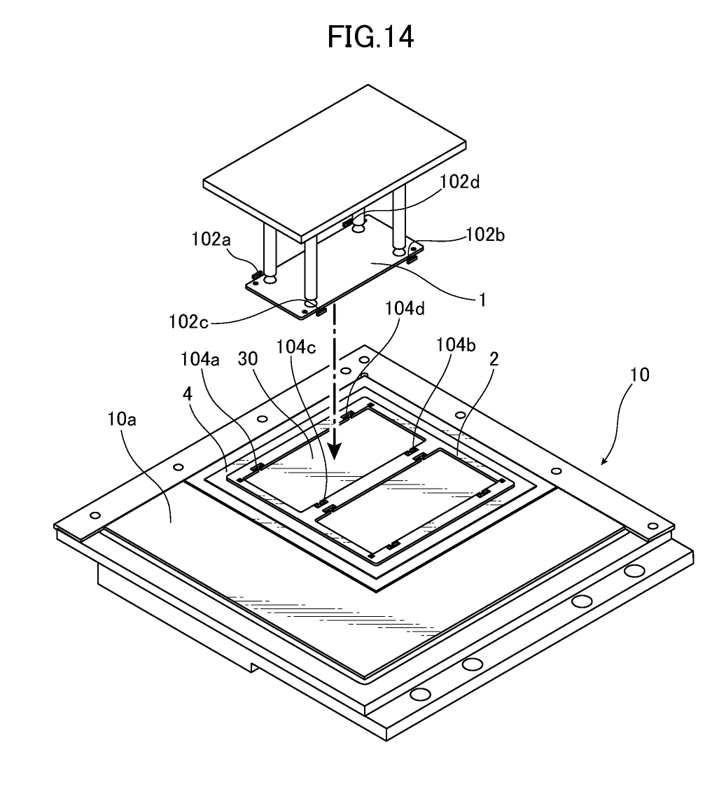

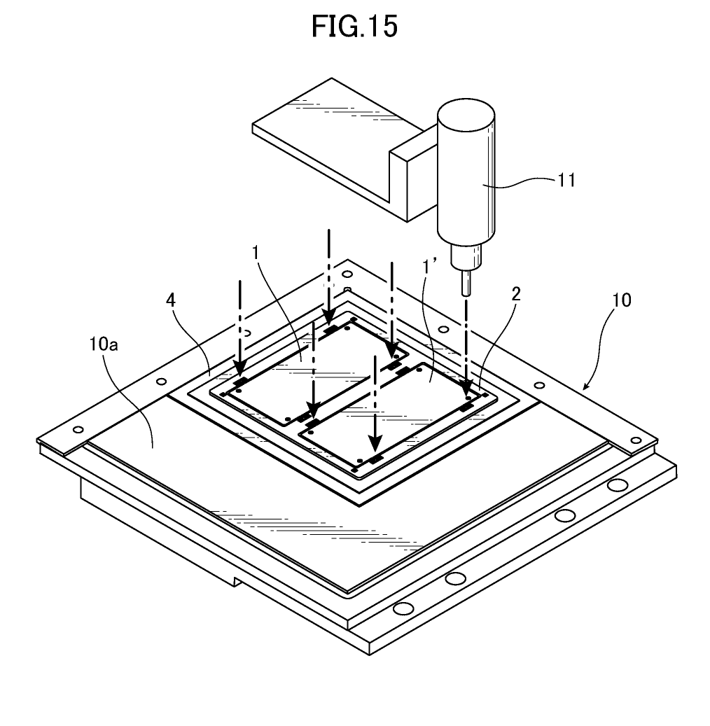

Then, the board piece conveyance mechanism 21 is moved to a position just above the retaining table 10 located in the first working area 42, and an image of the preliminarily-marked reference marks 100a, 100b, 100c, 100d of the frame 2 on the retaining table 10 is taken from thereabove by the imaging camera 12a mounted to the board piece conveyance mechanism 21. In the same manner as that for the board piece, respective X- and Y-coordinates of center positions of the reference marks 100 (100a to 100d) are compared with reach other to calculate an angular position of the frame 2, and, if necessary, after controllably rotating and/or translating (parallel-displacing) the retaining table 10 as illustrated in FIG. 13, calculate a rotated angle and/or a displacement amount, and the calculation result is also stored in the control unit. (S4). In accordance with the respective displacement and rotation amounts of the board piece 1 and the frame 2, the board piece conveyance mechanism 21, the retaining table conveyance mechanism 23 and the rotation mechanism for the retaining table 10 are operated, respectively, for a displacement in the X-direction, for a displacement in the Y-direction and for a rotation, to accurately perform positioning of the board piece 1 and the frame 2. After completion of the positioning, the board piece 1 suction-held by the suction pad 5 as illustrated in FIG. 14 is moved downwardly to a height position of the retaining table 10 and adhered onto the pressure-sensitive adhesive sheet 30 on the retaining table 10. Then, the board piece 1 is further pressed against the pressure-sensitive adhesive sheet 30 so that it is firmly fixed to the pressure-sensitive adhesive sheet 30. In the above manner, two board pieces 1 are received, respectively, in the engagement spaces 2a, 2b of the frame 2. In this embodiment, the four bridges 102a, 102b, 102c, 102d of the board piece 1 are engaged, respectively, with corresponding ones of the recesses 104a, 104b, 104c, 104d of the frame 2, so that the board piece 1 and the frame 2 are coupled together in the state illustrated in FIG. 8. Then, the negative pressure of the suction pad 5 of the board piece conveyance mechanism 21 is released to allow the suction pad 5 to be separated from the board piece 1 and backed upwardly. Further, an image of each of the board pieces 1 and the frame 2 is taken at a position set based on positional information obtained using the imaging camera 12a mounted to the board piece conveyance mechanism 21 (e.g., in a coupled region between the board piece 1 and the frame 2) to thereby measure an amount of mispositioning therebetween, and it is checked whether the amount falls within a prescribed value (e.g., within 50 μm). (S6). When the amount falls within the prescribed value, the process will advance to the next step. On the other hand, when the amount does not fall within the prescribed value, the multi-piece board 6 (unfinished multi-piece board) is removed as a defective.

Then, according to the retaining table conveyance mechanism 23, the retaining table 10 is moved in the Y-direction from the first working area 42 to the adhesive application position in the second working area 43, while passing below the linear guide 13 (13a, 13g).

Then, an image of the preliminarily-marked reference marks 100 (100a to 100d) or 101 (101a to 101d) of the frame 2 or each of the board pieces 1 is taken from thereabove in the vicinity of the dispenser 11 by the imaging camera 12c of the adhesive application unit. Respective center positions of the reference marks 100 (100a to 100d) or 101 (101a to 101d) are stored in the control unit. Further, respective X- and Y-coordinates of the center positions of the reference marks 100 (100a to 100d) or 101 (101a to 101d) are compared with reach other to calculate a deviation from a predetermined application route of the dispenser 11, and the calculation result is also stored in the control unit. (S7).

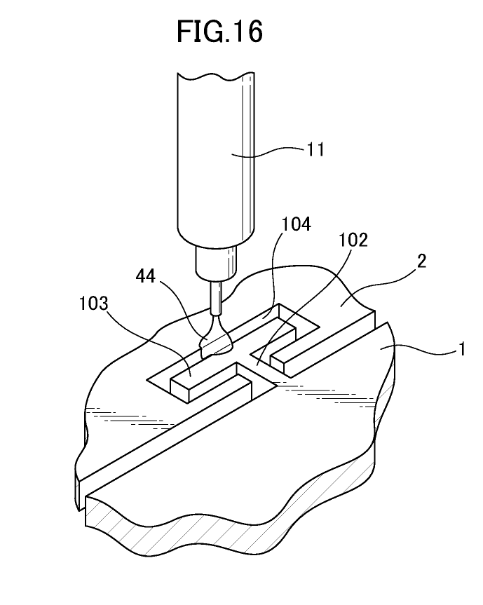

Then, the dispenser 11 is moved downwardly to the adhesive application position (a position close to the surface of the multi-piece board 6 (unfinished multi-piece board)). Further, by calculating an application route based on preliminarily-prepared positional information for applying the adhesive 44, etc., and controlling the movement mechanism of the adhesive application unit, the retaining table conveyance mechanism 23, and a discharge amount of the dispenser 11, the dispenser 11 is relatively moved with respect to the retaining table 10 to perform an adhesive charging operation in such a manner as to allow the adhesive 44 to be applied to a determined position, i.e., between an outer surface of a side edge of each of the enlarged distal ends 103a, 103b, 103c, 103d of the four bridges 102a, 102b, 102c, 102d of each of the board pieces 1, and an inner surface of a side edge of a corresponding one of the recesses 104a, 104b, 104c, 104d of the frame 2, as illustrated in FIG. 16. (S8).

As used in this application, the term “dispenser” may include a type comprising a needle assembly, a solenoid value and a jet body, and capable of discharging an adhesive to an object in a non-contact manner at a high speed, and controlling an amount of supply of the adhesive.

As such a dispenser 11 for applying the adhesive 44, it is possible to use, for example, DC-9500 produced by Nordson Corporation. An epoxy-based adhesive may be used as the adhesive 44.

Upon completion of the adhesive application, the retaining table 10 is moved to an ejection position by the retaining table conveyance mechanism 23. At the ejection position, the vacuum pump coupled to the retaining table 10 is deactivated to release the suction-holding of the metal plate 4 with respect to the retaining table 10.

The adhesive 44 applied to the multi-piece board 6 (unfinished multi-piece board) fixed to the metal plate 4 through the pressure-sensitive adhesive sheet 30 is subjected to thermal curing in a drying furnace or the like. A multi-piece board 6 after being subjected to thermal curing is peeled from the metal plate 4, and then subjected to a final appearance inspection. (S9). The use of the thermosensitive pressure-sensitive adhesive sheet makes it possible to easily peel the multi-piece board 6 from the pressure-sensitive adhesive sheet 30 at a relatively high temperature (about 60° C.), while minimizing warpage of the multi-piece board 6 occurring during peeling from the pressure-sensitive adhesive sheet 30.

In a situation where the frame 2 is disposed on one 10 of the two the retaining tables, an operation process comprises: causing the board piece conveyance mechanism 21 to extract and hold one of a stack of board pieces 1 stored in the board piece stacker 20; in this state, acquiring given positional information of the held board piece 1 in the above manner; and moving the board piece conveyance mechanism 21 in the X-direction to a position above the retaining table 10 located in the first working area 42 along the linear guide 13a. Then, the held board piece 1 is coupled to the frame 2 disposed on the retaining table 10 while adjusting a position of the held board piece 1. Then, the retaining table 10 is moved to the first working area 42 to the second working area 43, and the adhesive 44 is applied to the coupled region between each of the board pieces 1 and the frame 2, i.e., between corresponding ones of the bridges 102a, 102b, 102c, 102d each of the board pieces 1 and the recesses 104a, 104b, 104c, 104d of the frame 2, by using the dispenser 11, to thereby fix a positional relationship therebetween.

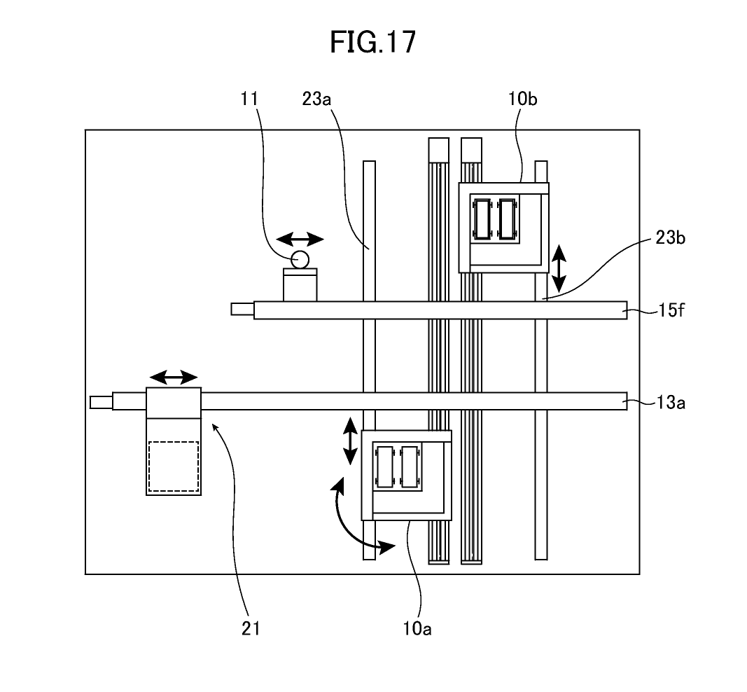

As one feature of the present invention, the retaining table comprises the pair of retaining tables 10a, 10b, and the retaining table conveyance mechanism comprises the pair of retaining table conveyance mechanisms 23a, 23b each configured to move a corresponding one of the retaining tables 10a, 10b from the first working area 42 to the second working area 43 in the Y-direction, as schematically illustrated in FIG. 17 in the form of a top plan view. Thus, in the present invention, the operation of coupling the board pieces 1 with the frame 2 and the operation of applying the adhesive 44 to the coupled region therebetween can be concurrently performed.

That is, in a first phase, during a period in which the operation of coupling the board pieces 1 with the frame 2 is performed in the first shuttle composed of the retaining table 10a and the retaining table conveyance mechanism 23a, the second shuttle composed of the retaining table 10b and the retaining table conveyance mechanism 23b is set in a standby state.

In a second phase, when the retaining table 10a of the first shuttle is moved to the second working area 43 to start the operation of applying the adhesive 44, the retaining table 10b in the second shuttle is concurrently moved to the first working area 42 to start the operation of coupling the board pieces 1 with the frame 2.

In a third phase, after completion of the adhesive application operation in the first shuttle, the multi-piece board 6 and the metal plate 4 are detached from the retaining table 10a, and another metal plate 4 with a frame 2 adhered on a new pressure-sensitive adhesive sheet 30 is disposed on the retaining table 10a, whereafter the retaining table 10a is returned from the second working area 43 to the first working area 42 to perform the operation of coupling the board pieces 1 with the frame 2, again. Concurrently, after completion of the coupling operation on the retaining table 10b of the second shuttle, the retaining table 10b is moved to the second working area to perform the adhesive application operation.

Then, in a fourth phase, the first shuttle performs the coupling operation, and the second shuttle performs the adhesive application operation.

In a fifth phase, contrary to the third phase, after completion of the adhesive application operation in the second shuttle, the multi-piece board 6 and the metal plate 4 are detached from the retaining table 10b, and another metal plate 4 with a frame 2 adhered on a new pressure-sensitive adhesive sheet 30 is disposed on the retaining table 10b, whereafter the retaining table 10b is returned from the second working area 43 to the first working area 42 to perform the operation of coupling the board pieces 1 with the frame 2, again. Concurrently, after completion of the coupling operation on the retaining table 10b of the first shuttle, the retaining table 10a is moved to the second working area to perform the adhesive application operation.

As above, the retaining tables 10a, 10b of the first and second shuttles are alternately located in the first working area 42 and the second working area 43 in such a manner as to concurrently perform the operation of coupling the board pieces 1 with the frame 2 using the board piece conveyance mechanism 21 and the operation of applying the adhesive by the dispenser 11, so that it becomes possible to drastically enhance operation efficiency of multi-piece board fabrication and improve productivity of a multi-piece board.

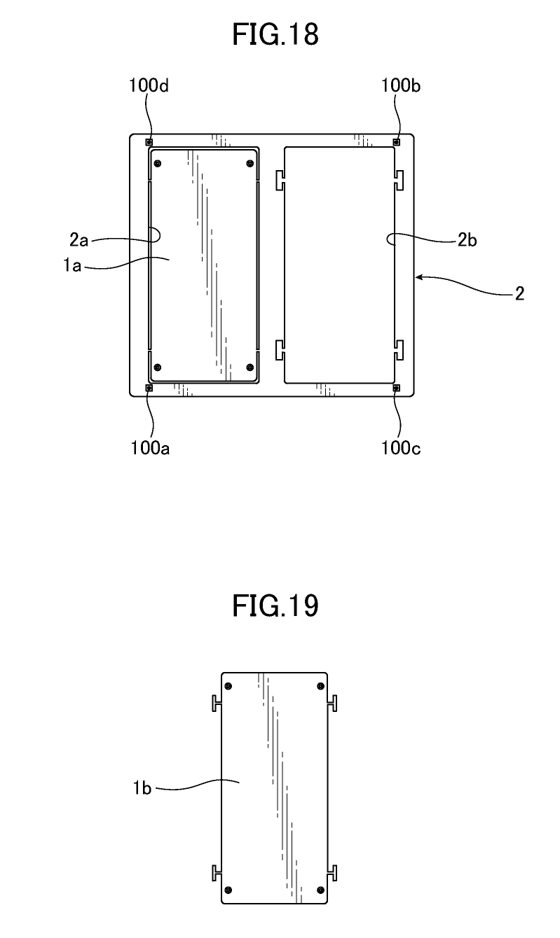

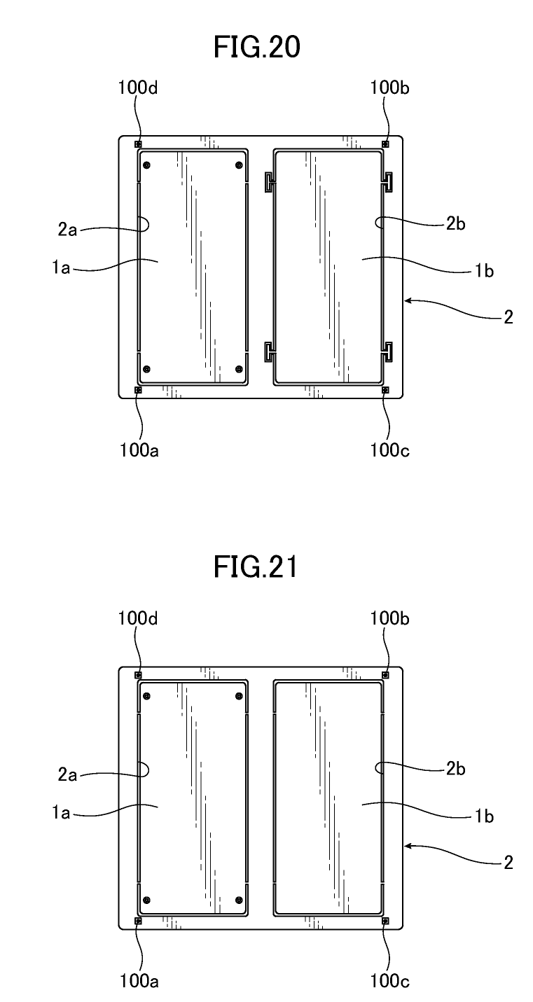

With reference to FIGS. 18 to 21, a second embodiment of the present invention will be described.

The second embodiment relates to a technique of fabricating a multi-piece board in a situation where, as a result of inspection after fabrication of a multi-piece board comprising two board pieces, it is determined that one of the board pieces satisfies performance criteria but the other board piece does not satisfy the performance criteria.

In such a situation, a non-defective board piece 1a fixed to one 2a of two spaces 2a, 2b of a frame 2 is left in the fixed state, whereas a board piece fixed to the other space 2d is detached from the frame after being determined as a defective board piece, as illustrated in FIG. 18. That is, the space 2b is in a vacant state. However, if a frame with only one non-defective board piece 1a is supplied to a subsequent step, operation efficiency in electronic product manufacturing will obviously deteriorate. On the other hand, if the frame with the non-defective board piece 1a is discarded, the non-defective board piece will be wasted.

A multi-piece board fabrication apparatus according to the second embodiment is capable of effectively functioning even in a situation where only one of two board pieces constituting a multi-piece board is a non-defective board piece, as well as being capable of manufacturing a multi-piece board comprising two non-defective board pieces.

In this case, first of all, in a first phase, in a first shuttle composed of a retaining table 10a and a retaining table conveyance mechanism 23a, a semifinished multi-piece board in which the board piece 1a has been already assembled into the space 2a of the frame 2 is provided and positioned on the retaining table 10a, and positional information of the frame is acquired. That is, respective X- and Y-coordinates of preliminarily-marked reference marks 100 (100a to 100d) of the frame 2 are compared with each other to determine a position of the frame 2. Further, if necessary, after controllably rotating and/or translating (parallel-displacing) the retaining table 10a as illustrated in FIG. 13, a rotated angle and/or a displacement amount is calculated and stored in a control unit.

On the other hand, as regards a board piece 1b to be engageably assembled into the void space 2b of the frame 2, the board piece conveyance mechanism 21 is moved toward a board piece stacker 20. A suction arm for applying a vacuum-suction force from the board piece conveyance mechanism 21 to a surface of a top one of a stack of board pieces 1b is moved downwardly, and operable, when the top board piece 1b is detected, to suction-hold the detected board piece 1b from thereabove by using a suction pad 5 attached to a distal end thereof and extract the suction-held board piece 1b from the board piece stacker 20. More specifically, after suction-holding the board piece 1b, the board piece conveyance mechanism 21 is moved upwardly to a position where the suction-held board piece 1b is subjected to image processing. Then, as illustrated in FIG. 12, an image of preliminarily-marked reference marks 101a, 101b, 101c and 101d of the board piece 1b being suction-held by the board piece conveyance mechanism 21 is taken from therebelow by the imaging camera 12b. Respective center positions of the reference marks 101a, 101b, 101c and 101d are stored in the control unit. Further, respective X- and Y-coordinates of the center positions of the reference marks 10 (101a to 101d) are compared with reach other to calculate a position and a rotational angle (angular position) of the suction-held board piece 1b, and the calculation result is also stored in the control unit. Then, in accordance with the respective displacement and rotation amounts of the board piece 1b and the frame 2 with respect to the engagement space 2b of the frame 2, calculated based on respective positional information of the frame 2 and the board piece 1b, the board piece conveyance mechanism 21, the retaining table conveyance mechanism 23a and a rotation mechanism for the retaining table 10a are operated, respectively, for a displacement in the X-direction, for a displacement in the Y-direction and for a rotation, to accurately perform positioning of the board 1b and the engagement space 2b of the frame 2. After completion of the positioning, the board piece 1b suction-held by the suction pad 5 as illustrated in FIG. 14 is moved downwardly to a height position of the retaining table 10a and adhered onto a pressure-sensitive adhesive sheet 30 on the retaining table 10a. Then, the board piece 1b is further pressed against the pressure-sensitive adhesive sheet 30 so that it is firmly fixed to the pressure-sensitive adhesive sheet 30. In the above manner, the board piece 1b is received in the engagement space 2b of the frame 2. In this embodiment, four bridges 102a, 102b, 102c, 102d of the board piece 1b are engaged, respectively, with corresponding ones of four recesses 104a, 104b, 104c, 104d of the engagement space 2b of the frame 2, so that the board piece 1b is precisely received in the engagement space 2b of the frame 2.

In the first phase, during a period in which the operation of coupling the board pieces 1b with the vacant space 2b of the frame 2 is performed in the first shuttle composed of the retaining table 10a and the retaining table conveyance mechanism 23a, a second shuttle composed of a retaining table 10b and a retaining table conveyance mechanism 23b is set in a standby state, under a condition that a semifinished multi-piece board in which one non-defective board piece 1a has been already assembled into one 2a of two engagement spaces of a frame 2, and the other engagement space 2b of the frame 2 is in a vacant state is mounted on the retaining table 10a.

In a second phase, on the first shuttle, the retaining table 1b mounting thereon the semifinished multi-piece board in a state in which the non-defective board piece 1b is engageably assembled in the space 2b of the frame 2 in the first phase is moved from a first working area 42 to a second working area 43. Then, in the second working area 43, an operation of applying an adhesive 44 by a dispenser 11 is started. Concurrently, in the first working area 42, the retaining table 10b of the second shuttle starts a coupling operation of engageably assembling the board piece 1b into the void engagement space 2b of the frame 2 to couple the board piece 1b with the frame 2.

In a third phase, after completion of the operation of applying the adhesive 44 in the first shuttle, a finished multi-piece board 6 and a metal plate 4 are detached from the retaining table 10a, and another semifinished multi-piece board is disposed on the retaining table 10a, whereafter the retaining table 10a is returned from the second working area 43 to the first working area 42 to perform the operation of coupling the board piece 1b with the frame 2, again. Concurrently, after completion of the coupling operation on the retaining table 10b of the second shuttle, the retaining table 10b is moved to the second working area to perform the adhesive application operation.

Then, in a fourth phase, the first shuttle performs the coupling operation, and the second shuttle performs the adhesive application operation.

In a fifth phase, contrary to the third phase, after completion of the adhesive application operation in the second shuttle, a multi-piece board 6 as a finished product comprising the frame in which the board pieces 1a, 1b are fixed, respectively, to the engagement spaces 2a, 2b thereof, and the metal plate 4, are detached from the retaining table 10b, and another semifinished multi-piece board in which a board piece 1a is fixed to only the engagement space 2a, and the other engagement space 2b is in a vacant state is disposed on the retaining table 10b, whereafter the retaining table 10b is returned to the first working area 42 to perform the operation of coupling the board pieces 1b with the frame 2. Concurrently, after completion of the coupling operation on the retaining table 10a of the first shuttle, the retaining table 10a is moved to the second working area 43 to perform the adhesive application operation.

As above, in the multi-piece board fabrication process in the second embodiment, even in a situation where one of two board pieces assembled into a multi-piece board is a defective, a new non-defective board piece can be effectively assembled into a void engagement space of a frame, so that it becomes possible to efficiently perform multi-piece board fabrication while achieving effective utilization of a frame and a board piece as components of a multi-piece board.

### INDUSTRIAL APPLICABILITY

As described above, the present invention makes it possible to efficiently perform multi-piece board fabrication, and therefore has industrial applicability.

### LIST OF REFERENCE SIGNS

1: non-defective board piece
2: frame
3: guide shaft
4: metal plate
5: suction pad
10a, 10b: retaining table
11: dispenser
12a, 12b, 12c: imaging camera
13a, 13b, 13d, 13e, 13f, 13g: linear guide
14a, 14b, 14d, 14e, 14f, 14g: drive motor
15a, 15b, 15c, 15d, 15e: ball screw
100a, 100b, 100c, 100d: reference mark (of frame)
101a, 101b, 101c, 101d: reference mark (of non-defective board piece)
102: bridge
103: enlarged distal end

1. An apparatus for fabricating a multi-piece board in which a plurality of board pieces are attached to a frame, comprising:
a working table having a horizontally spreading working area;
a linear guide extending in a first direction in such a manner as to divide the working area of the working table into a first working area and a second working area;
a board piece stacker disposed within the first working area and configured to releasably store a stack of non-detective board pieces;
a board piece conveyance mechanism attached to the linear guide at a position on the side of the first working area and configured to sequentially extract each of the board pieces stored in the board piece stacker and convey the extracted board piece to a given position along the first direction;
a retaining table disposed on the working table in such a manner as to be movable between the first and second working areas to allow positioning and fixing operations between the frame and each of the plurality of board pieces to be performed;
a retaining table conveyance mechanism supporting the retaining table and configured to move the retaining table over a range from the first working area to the second working area along a second direction perpendicular to the first direction; and
a dispenser installed to the linear guide at a position on the side of the second working area in such a manner as to be movable along the first direction and configured to supply an adhesive for bonding together the frame and each of the board pieces located on the retaining table,
wherein the apparatus are operable to cause the board piece conveyance mechanism to sequentially extract and hold each of the board pieces stored in the board piece stacker and couple the board piece with the frame placed on the retaining table located in the first working area, and, after moving the retaining table from the first working area to the second working area, apply the adhesive to a coupled region between the board piece and the frame by using the dispenser to thereby fix a positional relationship therebetween.

2. The apparatus as recited in claim 1, which comprises:
a first retaining table and a first retaining table conveyance mechanism configured to move the first retaining table over the range from the first working area to the second working area along the second direction; and
a second retaining table disposed adjacent to the first retaining table, and a second retaining table conveyance mechanism configured to move the second retaining table over the range from the first working area to the second working area along the second direction
wherein the apparatus is operable, when positioning and coupling operations between the frame and each of the board pieces are being performed on the first retaining table located in the first working area, to concurrently perform application of the adhesive to the coupled region between the frame and the board piece, on the second retaining table located in the second working area, and, when the positioning and coupling operations between the frame and each of the board pieces are being performed on the second retaining table located in the first working area, to concurrently perform the application of the adhesive to the coupled region between the first frame and the board piece in the second working area.

3. A method of fabricating a multi-piece board in which a plurality of board pieces are attached to a frame, using a multi-piece board fabrication apparatus comprising:
a working table having a horizontally spreading working area;
a linear guide extending in a first direction in such a manner as to divide the working area of the working table into a first working area and a second working area;
a board piece stacker disposed within the first working area and configured to releasably store a stack of non-detective board pieces;
a board piece conveyance mechanism attached to the linear guide at a position on the side of the first working area and configured to sequentially extract each of the board pieces stored in the board piece stacker and convey the extracted board piece to a given position along the first direction;
a retaining table disposed at a position on a side opposite to the board piece stocker with respect to a center of the first working area on the working table in the first direction, and configured to allow positioning and fixing operations between the frame and each of the plurality of board pieces to be performed;
a retaining table conveyance mechanism supporting the retaining table and configured to move the retaining table over a range from the first working area to the second working area along a second direction perpendicular to the first direction; and
a dispenser installed to the linear guide at a position on the side of the second working area in such a manner as to be movable along the first direction and configured to supply an adhesive for bonding together the frame and each of the board pieces located on the retaining table,
the method comprising:
causing the board piece conveyance mechanism to sequentially extract and hold each of the board pieces stored in the board piece stacker;
moving the board piece conveyance mechanism in the first direction to the given position along the linear guide and then performing positioning and coupling between the board piece and the frame placed on the retaining table located in the first working area;
moving the retaining table from the first working area to the second working area; and
applying the adhesive to a coupled region between the board piece and the frame by using the dispenser to thereby fix a positional relationship therebetween.

4. The method as recited in claim 3, wherein the multi-piece board fabrication apparatus further comprises:
a first retaining table and a first retaining table conveyance mechanism configured to move the first retaining table over the range from the first working area to the second working area along the second direction; and
a second retaining table disposed adjacent to the first retaining table, and a second retaining table conveyance mechanism configured to move the second retaining table over the range from the first working area to the second working area along the second direction
and wherein the method comprising:
when positioning and coupling operations between the frame and each of the board pieces are being performed on the first retaining table located in the first working area, to concurrently perform application of the adhesive to the coupled region between the frame and the board piece, on the second retaining table located in the second working area; and
when the positioning and coupling operations between the frame and each of the board pieces are being performed on the second retaining table located in the first working area, to concurrently perform the application of the adhesive to the coupled region between the first frame and the board piece in the second working area.

5. A method of fabricating a multi-piece board in which a plurality of board pieces are attached to a frame, comprising:
forming a plurality of board pieces constituting a single board for mounting a given electronic component;
separating the formed board pieces into a group of non-defective board pieces having good quality satisfying a given criterion and a group of defective board pieces unsatisfying the given criterion, and selecting only the non-defective board pieces;
providing a single-piece frame for supporting a plurality of board pieces, and engaging a plurality of the non-defective board pieces each having a bridge provided on a side edge thereof to protrude outwardly from the side edge, with recesses of the frame for receiving therein respective ones of the bridges of the non-defective board pieces, via the bridges;
adhering the frame and the non-defective board pieces engaged with the frame onto a pressure-sensitive adhesive sheet; and
bonding together corresponding ones of the bridges of the non-defective board pieces and the recesses of the frame by an adhesive.

6. The method as recited in claim 5, wherein the pressure-sensitive adhesive sheet is supported by a metal plate.

7. The method as recited in claim 5, wherein the pressure-sensitive adhesive sheet has a property that high adhesion is exhibited at a relatively low temperature, and the adhesion deteriorates at a relatively high temperature.

8. The method as recited in claim 5 which further comprises: attaching a multi-piece board having the non-defective board pieces integrated with the frame onto a pressure-sensitive adhesive sheet at the relatively low temperature; and separating the multi-piece board from the pressure-sensitive adhesive sheet at the relatively high temperature.

9. The method as recited in claim 8, wherein the relatively low temperature is 10 to 30° C., and the relatively high temperature is 60° C. or more.

10. The method as recited in claim 7, wherein the operation of providing includes acquiring respective positional information of the frame and each of the non-defective board pieces, and establishing engagement therebetween while controlling positions thereof based on the position information.

11. The method as recited in claim 7, which further comprises acquiring positional information of a given location of the frame and the non-defective board pieces adhered onto the pressure-sensitive adhesive sheet, by using an imaging camera, and storing the acquired positional information.

12. The method as recited in claim 11, wherein the frame has at least two engagement spaces each capable of receiving therein the non-defective board piece, and wherein the operation of providing includes providing the frame in a state in which at least one of the engagement spaces is vacant without receiving therein any board piece.

13. An apparatus for fabricating a multi-piece board, wherein the multi-piece board comprises: a non-defective board piece having good quality satisfying a given criterion, selected from among a plurality of board pieces constituting a single board for mounting a given electronic component; and a frame for supporting a plurality of the non-defective board piece, and wherein each of the non-defective board pieces has a bridge provided on a side edge thereof and formed to protrude outwardly from the side edge, and the frame is provided with recesses engageable with the respective bridges of the non-defective board pieces during engagement between the frame and the non-defective board pieces,
the apparatus comprising:
a pressure-sensitive adhesive sheet for allowing an integral structure of the frame and the plurality of non-defective board pieces engaged with each other to be adhered thereonto; and
a dispenser operable, after the integral structure of the frame and the plurality of non-defective board pieces is adhered onto the pressure-sensitive adhesive sheet and positioned, to supply an adhesive for bonding together corresponding ones of the recesses of the frame and the bridges of the non-defective board pieces.

14. The apparatus as recited in claim 13, wherein the pressure-sensitive adhesive sheet is supported by a metal plate.

15. The apparatus as recited in claim 14, which further comprises a positional information acquisition device configured to acquire positional information of a given location of the frame and positional information of a given location of each of the non-defective board pieces supported by the frame.

16. The apparatus as recited in claim 15, wherein the positional information acquisition device is configured to acquire the positional information by analyzing images which are taken from the frame and the non-defective board pieces supported by the frame, by using a CCD camera.

17. The apparatus as recited in claim 16, wherein the CCD camera includes a first CCD camera for acquiring the positional information of the non-defective board pieces, and a second CCD camera for acquiring the positional information of the frame.

18. The apparatus as recited in claim 17, wherein the first CCD camera is disposed to take an image of each of the non-defective board pieces from therebelow, and the second CCD camera is disposed to take an image of the frame from thereabove.

19. The apparatus as recited in claim 14, which further comprises:
a retaining table retaining the metal plate supporting the multi-piece board adhered onto the pressure-sensitive adhesive sheet; and
a position control mechanism configured to control a position of the retaining table.

20. The apparatus as recited in claim 19, which further comprises:
an arm configured to conveyably hold the non-defective board piece; and
an arm movement mechanism configured to move the arm and control a position of the arm.

21. The apparatus as recited in claim 19, wherein the position control mechanism comprises a mechanism configured to control a rotational position of the retaining table.

22. The apparatus as recited in claim 21, which is configured to control respective positions of the arm and the retaining table to thereby couple each of the non-defective board pieces with the frame.

23. The apparatus as recited in claim 22, which further comprises a control mechanism configured to control a position of the dispenser, the control mechanism being operable, after completion of the engagement between the frame and the non-defective board pieces, to positionally control the dispenser to supply the adhesive to a bonding region between corresponding ones of the bridges of the non-defective board pieces and the recesses of the frame.

24. The apparatus as recited in claim 23, wherein the pressure-sensitive adhesive sheet has a property that high adhesion is exhibited at a relatively low temperature, and the adhesion deteriorates at a relatively high temperature.

25. The apparatus as recited in claim 22, wherein the relatively low temperature is 10 to 30° C., and the relatively high temperature is 60° C. or more.

26. The apparatus as recited in claim 25, wherein the frame has at least two engagement spaces each capable of receiving therein the non-defective board piece, and wherein at least one of the engagement spaces is vacant without receiving therein any board piece.
